(19) United States
(12) Patent Application Publication
(10) Pub. No.: US 2011/0049318 A1
(43) Pub. Date: Mar. 3, 2011

(54) SUPPORT SYSTEM FOR RECEIVING COMPONENTS IN TELECOMMUNICATION AND DATA TECHNOLOGY

(76) Inventors: Ulrich Hetzer, Mahlow (DE); Eberhard Kahle, Berlin (DE)

(21) Appl. No.: 12/918,937

(22) PCT Filed: Jan. 12, 2009
(86) PCT No.: PCT/EP2009/000101

§ 371 Date: Nov. 18, 2010

(30) Foreign Application Priority Data
Feb. 26, 2008 (DE) 10 2008 011 159.7

(51) Int. Cl. H05K 7/14

(52) U.S. Cl. 248/231.81

(57) ABSTRACT

The invention relates to a mount system (3) for accommodating components from telecommunications and data technology, comprising means for accommodating components from telecommunications and data technology and means for fixing the mount system (3) on a mount rack, the means for fixing the mount system (3) being in the form of snap-action operating levers (6), which are loaded by spring force and are arranged pivotably about an axis of rotation on the mount system (3).

The invention relates to a mount system for accommodating components from telecommunications and data technology, the mount system having means for accommodating components from telecommunications and data technology and means for fixing the mount system on a mount rack.

Components from telecommunications and data technology are known which are formed with means for fixing them on a mount rack, for example two spaced-apart round bars. In particular in the case of modular built-on accessories, however, this is disadvantageous since of these all the means need to be connected simultaneously to the mount rack, which requires a great deal of expenditure of force. A further disadvantage is the fact that a subsequent displacement on the mount rack is only possible with difficulty since the large number of means produce a very high holding force.

The invention is based on the technical problem of providing a mount system for accommodating components from telecommunications and data technology which solves the described problems.

The solution to the technical problem results from the subject matter having the features of claim 1.

In this regard, the mount system for accommodating components from telecommunications and data technology comprises means for accommodating components from telecommunications and data technology and means for fixing the mount system on a mount rack, the means for fixing the mount system being in the form of snap-action operating levers, which are spring loaded and are arranged pivotably about an axis of rotation on the mount system. Preferably, the snap-action operating levers are used for the fixing to round bars, further preferably a snap-action operating lever being provided for each round bar. As a result of the preferably two snap-action operating levers, the mount system can be latched on easily, for which purpose the snap-action operating levers are moved in the direction toward one another or, when the mount system or module is inserted, are automatically opened by the bars. If the user then lets go of the snap-action operating levers or the levers snap back, the springs, which are preferably prestressed, are relieved of strain and the snap-action operating levers engage behind the bars of the mount rack. For displacement purposes, the user then reaches past laterally, for example, presses the snap-action operating levers inwards and moves the mount system along the bars. Owing to the fact that the necessary force for unlatching acts laterally, unintentional removal of the assembly is also virtually ruled out.

In a preferred embodiment, the spring is supported on the housing of the snap-action operating lever and on the mount system, further preferably on an edge of the snap-action operating lever and on a rib of the mount system.

In a further preferred embodiment, the spring is formed by a part of the lever which can be prestressed. For example, the lever and the spring are in the form of an integral injection-molded part or an integral metal part, with the result that the spring is an integral component part of the lever. Alternatively, the plastic of the lever can be injected around the metallic spring.

The invention will be explained in more detail below with reference to a preferred exemplary embodiment. In the figures:

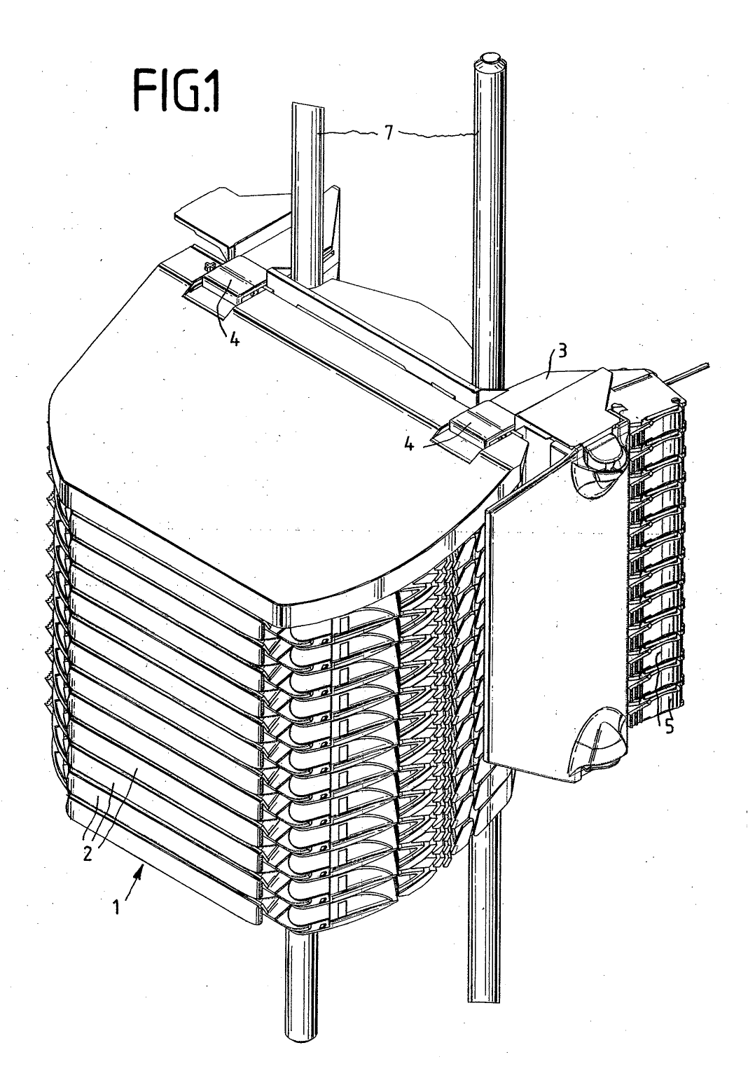

FIG. 1 shows a perspective front view of a splicing module on a mount system,

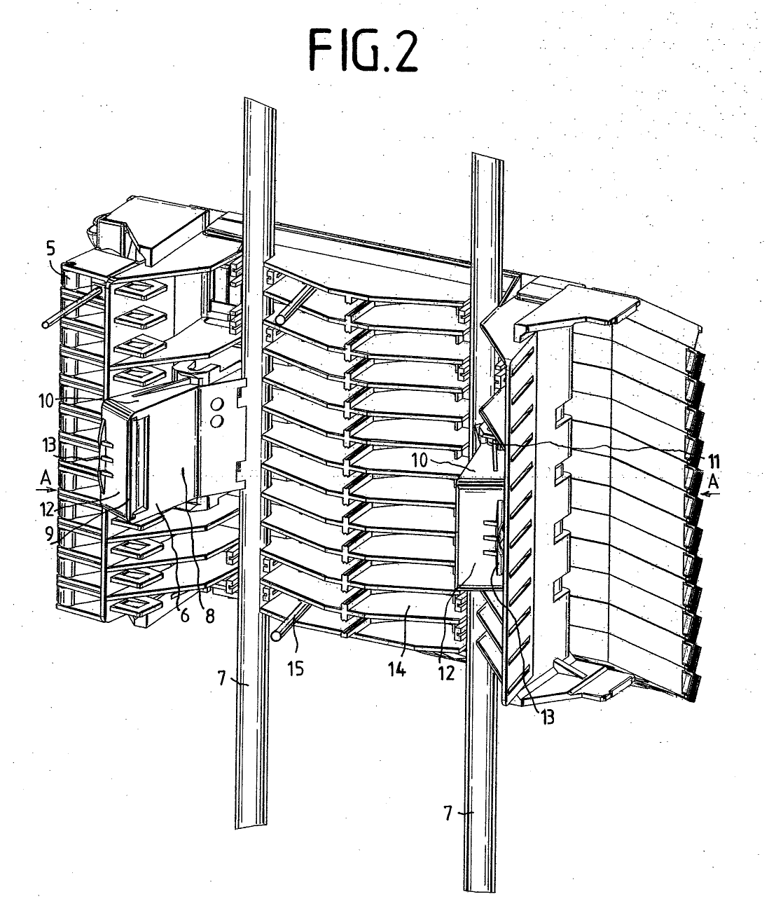

FIG. 2 shows a perspective rear view of the splicing module of the mount system,

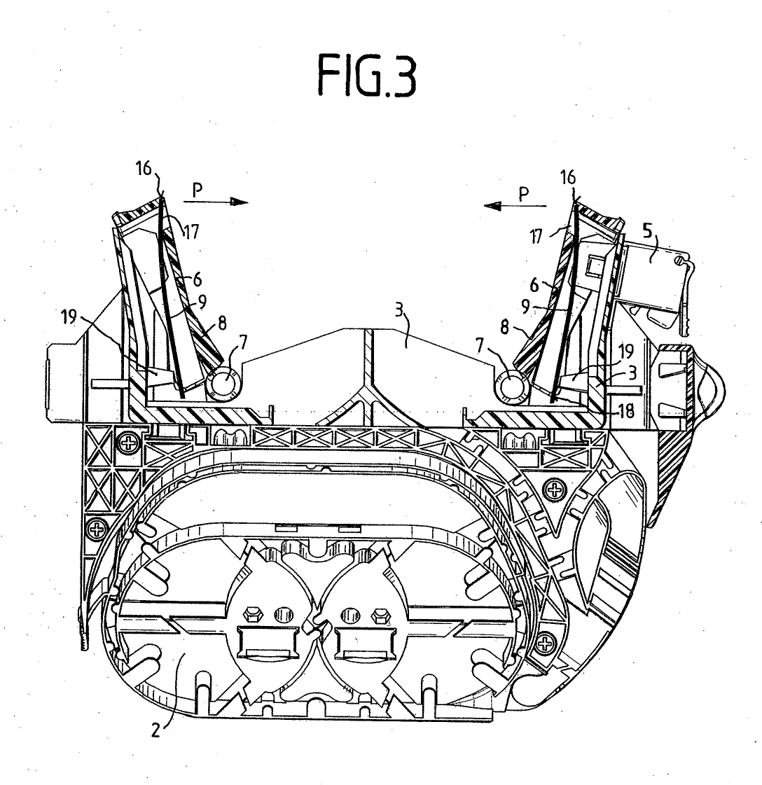

FIG. 3 shows a sectional illustration through the mount system, and

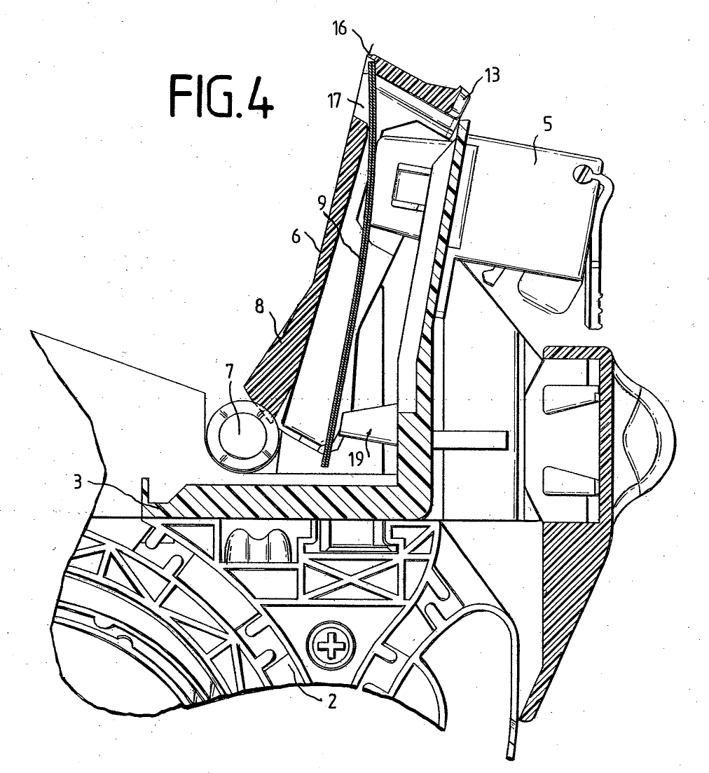

FIG. 4 shows a detailed illustration of the sectional illustration shown in FIG. 3.

FIG. 1 illustrates a splicing module 1, which comprises a large number of splicing cassettes 2. The splicing module 1 is latched on to a mount system 3, the mount system 3 and the splicing module 1 additionally being connected to one another by means of two clip elements 4. Cable holders 5 are latched laterally on the mount system 3. The mount system 3 is fixed on two round bars 7 by means of snap-action operating levers 6 (see FIG. 2). Instead of the splicing module 1, other structural units from telecommunications and data technology can also be connected to the mount system 3.

The snap-action operating levers 6 comprise a housing 8, in which a spring 9 is supported in prestressed fashion. On the upper side 10 and the lower side, the housing has pins 11, which can be inserted into corresponding openings of the mount system 3, with the result that the snap-action operating lever 6 can be mounted pivotably about the pins 11 as the axis of rotation. On the front end side 12, the housing 8 has a grip face by means of which the snap-action operating levers 6 can be moved more easily. Further cable guides 14 of the mount system 3, via which optical fiber cables 15 can be guided to the splicing cassettes 2 (FIG. 1), are illustrated between the round bars 7.

FIG. 3 or 4 illustrates a cross section along the section line A-A through the splicing module 1 and the mount system 3, this section running in such a way that the upper side 10 of the housing 8 of the snap-action operating levers 6 is cut away. The spring 9 is supported on an edge 16 of the end side 12 of the housing 8. The housing 8 also has two openings 17, 18, through which the spring 9 can be inserted into the housing 8. Furthermore, the spring 9 is supported on a rib 19 of the mount system 3, the housing 8 likewise having an opening in the region of the rib 19. In the fixed position of the snap-action operating lever 6 illustrated, said snap-action operating lever 6 engages behind the round bars 7. For unlatching purposes, the two snap-action operating levers 6 are bent in the arrow directions P illustrated. As a result of the dimensions of the spring 9, the desired holding force can in this case be set in wide ranges.

### LIST OF REFERENCE SYMBOLS

1 Splicing module
2 Splicing cassette
3 Mount system
4 Clip element
5 Cable holders
6 Snap-action operating levers
7 Round bars
8 Housing
9 Spring
10 Upper side
11 Pins
12 End side
13 Grip face
14 Cable guides
15 Optical fiber cable
16 Edge
17, 18 Openings
19 Rib

1. A mount system for accommodating components from telecommunications and data technology, comprising means for accommodating components from telecommunications and data technology and means for fixing the mount system on a mount rack, wherein the means for fixing the mount system are in the form of snap-action operating levers, which are loaded by spring force and are arranged pivotably about an axis of rotation on the mount system.

2. The mount system as claimed in claim 1, wherein the spring is supported on the housing of the snap-action operating lever and on the mount system.

3. The mount system as claimed in claim 2, wherein the spring of the snap-action operating lever is supported on an edge of the snap-action operating lever and on a rib of the mount system.

4. The mount system as claimed in claim 1, wherein the spring is formed by a part of the lever which can be prestressed.
